(19) United States
(12) Patent Application Publication
(10) Pub. No.: US 2014/0042001 A1
(43) Pub. Date: Feb. 13, 2014

(54) PANEL WITH SENSING STRUCTURE AND MANUFACTURING METHOD THEREOF

(71) Applicant: Wistron Corporation, New Taipei City (TW)

(72) Inventor: Kuei-Ching Wang, New Taipei City (TW)

(73) Assignee: Wistron Corporation, New Taipei City (TW)

(21) Appl. No.: 13/960,794

(22) Filed: Aug. 6, 2013

(30) Foreign Application Priority Data
Aug. 9, 2012 (TW) 101128786
Sep. 21, 2012 (TW) 101134786

(51) Int. Cl. H03K 17/96; H01H 11/00

(52) U.S. Cl. CPC H03K 17/9618; H01H 11/00
USPC 200/295; 29/622

(57) ABSTRACT

A panel with a sensing structure includes a photoresist adhesion layer with a first surface and a second surface opposite to the first surface; a first conductive layer with a plurality of first conductive patterns disposed on the first surface along a first direction in sequence; and a second conductive layer with a plurality of second conductive patterns disposed on the second surface along a second direction in sequence.

### BACKGROUND OF THE INVENTION

1. Field of the Invention

The present invention relates to a panel, and more particularly, to a panel with a sensing structure and manufacturing method thereof .

2. Description of the Prior Art

Various types of touch control input technology are widely utilized in electronic devices. For example, a mobile phone and a tablet utilizing touch panels as input interfaces are common. A user can issue commands via using a hand to touch the touch panel easily, or can move a cursor and input handwriting words via dragging the hand on a surface of the touch panel. A display panel equipped with a touch panel also can display virtual keyboards, for allowing a user to input corresponding words through the virtual keyboards.

Generally, the touch panels can be classified as resistive, capacitive, acoustic pulse and infrared, wherein the products with resistive touch panels are most common. According to designs of the resistive touch panels, the resistive touch panels can be classified as 4-wire, 5-wire, 6-wire, 8-wire, etc. Since the resistive touch panel is not as sensitive as a conductive touch panel and multi-point touch technology is more mature on the conductive touch panel, the conductive touch panel has been widely applied to various kinds of product, however.

A conventional touch panel includes two substrates and conductive patterns, a trace layer, an insulation layer and flexible printed circuit board patterns formed on the substrates, wherein the conductive patterns, the trace layer, the insulation layer and the flexible printed circuit board patterns are disposed between the substrates. The conventional touch panel has a thick thickness, and therefore, is not flexible due to effects of materials of the conductive patterns; the conventional touch panel thereby does not comply with the trend of the times.

On the other hand, the conventional touch panel generally uses optically clear adhesive (O.C.A) as an adhesive between the conductive patterns. The thickness of the convention touch panel cannot be thinning, therefore, which resulting in difficulties of making the electronic device light and thin and reducing the power consumption of the display module.

Thus, how to provide a panel with a sensing structure having thin thickness and low display power consumption, and how to effectively simplify processes of the panel with the sensing structure have become important issues in the industry.

### SUMMARY OF THE INVENTION

According to the abovementioned issues, the present invention provides a panel with a sensing structure which has smaller thickness and low display power consumption and is capable of simplifying the process, and manufacturing method thereof.

In order to achieve the abovementioned goals, the present invention discloses a panel with sensing structure. The panel comprises a photoresist adhesion layer, a first conductive layer and a second conductive layer. The first and second conductive layers have a plurality of first conductive patterns and a plurality of second conductive patterns. The photoresist adhesion layer has a first surface and a second surface opposite to the first surface. The first conductive patterns are disposed on the first surface along a first direction in sequence. The second conductive patterns are disposed on the second surface along a second direction in sequence.

In an embodiment of the present invention, the first conductive patterns or the second conductive patterns are metal conductive patterns. When the conductive patterns are the metal conductive patterns, materials of the metal conductive patterns comprises a plurality of silver particles, wherein the diameters of the sliver particles are within 1 nm to 100 nm.

In an embodiment of the present invention, the first conductive layer comprises an internal substrate; the first conductive patterns are transparent conductive patterns; and the first conductive patterns are formed on the internal substrate and disposed on the photoresist adhesion layer via the internal substrate.

In an embodiment of the present invention, the first conductive patterns extend along the second direction and the second conductive patterns extend along the first direction; wherein the first direction is perpendicular to the second direction.

In an embodiment of the present invention, the panel with the sensing structure further comprises a first substrate, disposed on the first conductive patterns; a protection layer, disposed to be opposite to the first substrate; a shielding layer, disposed on borders of the protection layer; and an adhesion layer, disposed between the first substrate and the protection layer; wherein the first substrate is a flexible transparent substrate.

In an embodiment of the present invention, the panel with the sensing structure further comprises an external substrate, adhered to the second conductive layer; a protection layer, disposed to be opposite to the first conduction layer; a shielding layer, disposed on borders of the protection layer; and an adhesion layer, disposed between the first conductive layer and the protection layer; wherein the external substrate is a flexible transparent substrate.

In an embodiment of the present invention, the panel with the sensing structure further comprises a protection layer, disposed to be opposite to the first conduction layer; a shielding layer, disposed on borders of the protection layer; and an adhesion layer, disposed between the first conductive layer and the protection layer.

In order to achieve the abovementioned goals, the present invention discloses a manufacturing method of a panel with a sensing structure. The manufacturing method comprises disposing a first conductive layer with a plurality of first conductive patterns on a first substrate; adhering the first substrate and a second substrate via a photoresist adhesion layer; forming a second conductive layer with a plurality of the second conductive patterns on the second substrate; and removing the second substrate.

In an embodiment of the present invention, the first conductive layer comprises an internal substrate; the first conductive patterns are transparent conductive patterns; and the first conductive patterns are formed on the internal substrate and disposed on the photoresist adhesion layer via the internal substrate.

In an embodiment of the present invention, the manufacturing method further comprises forming a shielding layer on borders of a protection layer; and adhering the first substrate and the protection layer via an adhesion layer.

In an embodiment of the present invention, the manufacturing method further comprises forming a shielding layer on borders of a protection layer; and adhering the second conductive layer and the protection layer via an adhesion layer.

In an embodiment of the present invention, the manufacturing method further comprises removing the first substrate; forming a shielding layer on borders of a protection layer; and adhering the first conductive layer and the protection layer via an adhesion layer.

In an embodiment of the present invention, the first conductive patterns or the second conductive patterns are metal conductive patterns. When the conductive patterns are the metal conductive patterns, materials of the metal conductive patterns comprises a plurality of silver particles and the diameters of the silver particles are within 1 nm to 100 nm.

To sum up, the panel with the sensing structure and manufacturing method thereof of the above embodiments are suitable for a touch sensing medium utilizing metal conductive patterns with high transmittance, high conductivity and flexibility as the conductive layer. The panel with the sensing structure and manufacturing method thereof of the above embodiments can replace semiconductor oxides of the conventional process which are high cost and low yield, and are provided with advantages of allowing products to be thinner and flexible and simplifying the process. For retaining current instrument cost and high practicality, the present invention also can incorporate with the semiconductor oxides since the emphasis of the above embodiments is utilizing the photoresist adhesion layer with high transmittance for performing adhesion, such that the power consumption of the display module is reduced and the viewing brightness is increased, effectively.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A and FIG. 1B are schematic diagrams of a panel with sensing structure according to an embodiment of the present invention.

FIG. 1C is a schematic diagram of an exemplary alternation of the panel shown in FIG. 1B.

FIG. 2 is a cross section view of a panel with a sensing structure according to another embodiment of the present invention.

FIG. 3A and FIG. 3B are schematic diagrams of panels with sensing structures according to embodiments of the present invention.

FIG. 4 is a flow chart of a manufacturing method of a panel with a sensing structure according to an embodiment of the present invention.

### DETAILED DESCRIPTION

In the following description, a panel with a sensing structure and manufacturing method thereof according to embodiments of the present invention are illustrated by related figures, wherein the same components utilize the same symbols.

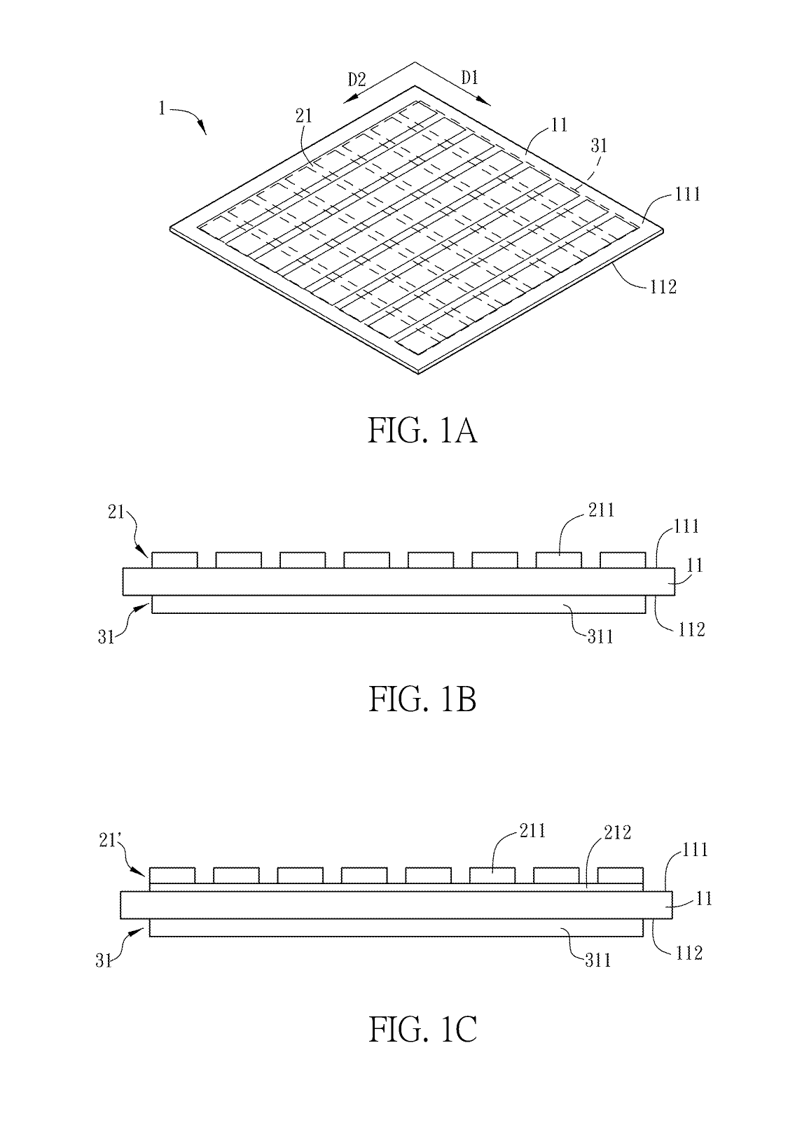

Please refer to FIG. 1A and FIG. 1B, which are schematic diagrams of a panel 1 with a sensing structure according to an embodiment of the present invention. The panel 1 comprises a photoresist adhesion layer 11, a first conductive layer 21 and a second conductive layer 31. The first conductive layer 21 comprises a plurality of first conductive patterns 211 and the second conductive layer 31 comprises a plurality of second conductive patterns 311. The photoresist adhesion layer 11 comprises a first surface 111 and a second surface 112 opposite to the surface 111. In this embodiment, materials of the photoresist adhesion layer 11 comprise a resin and a sensitizer, wherein the resin is utilized as a binder and the sensitizer is a positive photoresist sensitizer or a negative photoresist sensitizer. The first conductive patterns 211 are disposed along a first direction D1, sequentially, on the first surface 111 of the photoresist adhesion layer 11 and extend along a second direction D2. The second conductive patterns 311 are disposed along the second direction D2, sequentially, on the surface 112 of the photoresist adhesion layer 11 and extend along the first direction D. Practically, the first conductive patterns 211 and the second conductive patterns 311 can be metal conductive patterns for providing better flexibility and increasing the completion degree of the panel 1. When the first conductive patterns 211 and the second conductive patterns 311 are the metal conductive patterns, the materials of the first conductive patterns 211 and the second conductive patterns 311 can be photosensitive conductive materials comprising a photosensitive resin mixture and a plurality of silver particles.

The diameters of the silver particles are within 1 nm to 100 nm, and are within 1 nm to 50 nm preferably. In addition, the photosensitive resin mixture occurs crosslinking reactions when the photosensitive resin mixture is exposed to light, and thereby the first conductive patterns 211 and the second conductive patterns 311 can be disposed via the photolighigraphy process.

Besides, the first direction D1 is perpendicular to the second direction D2 (e.g. the first direction D1 is the X-axis and the second direction D2 is the Y-axis). The first conductive patterns 211 and the second conductive patterns 311 are utilized for defining touch sensing circuit and for detecting X-axis positions and Y-axis positions of touch inputs. In other words, the first conductive patterns 211 and the second conductive patterns 311 form a sensing structure.

Please note that, in this embodiment, the first conductive patterns 211 for sensing the X-axis positions of the touch inputs are disposed on the surface 111 of the photoresist adhesion layer 11 as an example. In practical, the first conductive patterns can be disposed on the second surface 112 of the photoresist adhesion layer 11, and the second conductive patterns 311 can be disposed on the first surface 111 of the photoresist adhesion layer 11.

Since the first conductive patterns 211 and the second conductive patterns 311 are consisted of the materials comprising the photosensitive resin mixture and the plurality of silver particles, the first conductive patterns 211 and the second conductive patterns 311 not only have high transmittance and high conductivity but also have the flexibility.

FIG. 1C is a schematic diagram of an exemplary alternation of the panel 1 shown in FIG. 1B. In this embodiment, the first conductive layer 21′ comprises not only the plurality of first conductive patterns but also an internal substrate 212. In such a condition, the first conductive patterns 211 can be transparent conductive patterns and the materials thereof comprise indium tin oxide (ITO), for example. The second conductive layer 31 and the second conductive patterns 311 can be made of the abovementioned photosensitive conductive material, however. Since the first conductive patterns 211 are formed on the internal substrate 212, the first conductive patterns 211 are disposed on the first surface 111 via the internal substrate 212. In this embodiment, the flexibility of the panel 1 maybe partly decreased since the transparent conductive layers such as the indium tin oxide are used, but the usability of this embodiment becomes higher since these transparent conductive layers are more common in the industry. Furthermore, since the indium tin oxide are originally coated on the internal substrate 212 before patterning, the process of this embodiment can be simplified via applying materials provided by a third party. The internal substrate 212 can be a membranous substrate such as a Polyimide (PI) transparent membranous substrate and a Polyethylene terephthalate (PET) transparent membranous substrate.

The following descriptions will refer to the embodiment shown in FIG. 1B. One with ordinary skill in the art should be capable of replacing the embodiment shown in FIG. 1B by the embodiment shown in FIG. 1C, and thus the details of replacing the embodiment shown in FIG. 1B by that shown in FIG. 1C are not narrated herein for brevity.

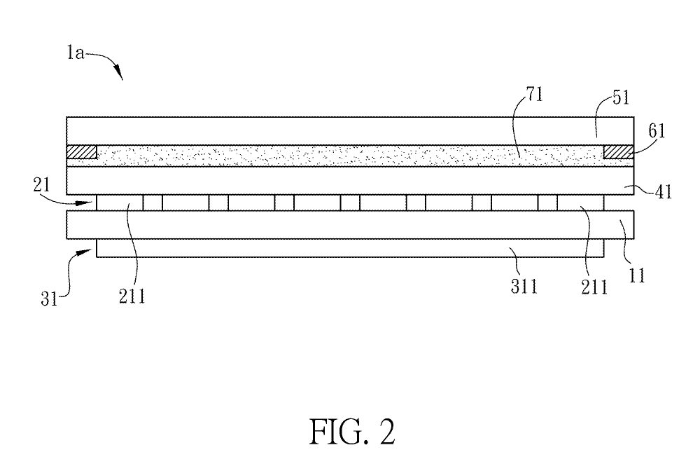

FIG. 2 is a cross-sectional view of a panel 1a with a sensing structure according to another embodiment of the present invention. A photoresist adhesion layer 11, a first conductive layer 21 and a second conductive layer 31 of the panel 1a are similar to those of panel 1 shown in FIG. 1B, and thus are not described herein for brevity. In this embodiment, a number of the first conductive patterns 211 and a number of the second conductive patterns 311 are 5 as an example, but are not limited herein. In practical, the number of the first conductive patterns 211 and the number of the second conductive patterns 311 can be different according to specifications of products and designs of circuitry.

The panel 1a further comprises a first substrate 41 on the first conductive patterns 211, a protection layer 51, a shielding layer 61 and an adhesion layer 71. In a realization, the first substrate 41 is a transparent substrate or a transparent membranous substrate such as a Polyimide (PI) transparent membranous substrate and a Polyethylene terephthalate (PET) transparent membranous substrate, preferably, for achieving features of transparent, thin and flexible.

The protection layer 51 is disposed to be opposite to the first substrate 41 and the materials of the protection layer 51 can be the polyimide or the polyethylene terephthalate. In other applications, the protection layer 51 can be realized in a glass, especially a thin flexible glass or a soft glass. The shielding layer 61 is disposed on borders of the protection layer 51 for shielding border traces (not shown) neighbored the first conductive patterns 211 and the second conductive patterns 311. Materials of the shielding layer 61 are insulation materials or inks of various colors which are insulated, for example. The adhesion layer 71 is disposed between the first substrate 41 and the protection layer 51 for adhering first substrate 41 and the protection layer 51. The adhesion layer 71 is the optically clear adhesive or the same materials of the abovementioned photoresist adhesion layer 11. Besides, the panel 1a can be adhered to a liquid crystal display (LCD) module via the optically clear adhesive or other transparent adhesives, for forming a touch displayer.

Please note that, the ratios between the lengths, the widths and the thicknesses of each components shown in the above figures are only used for illustrating purpose, and do not represent the actual ratios in practical.

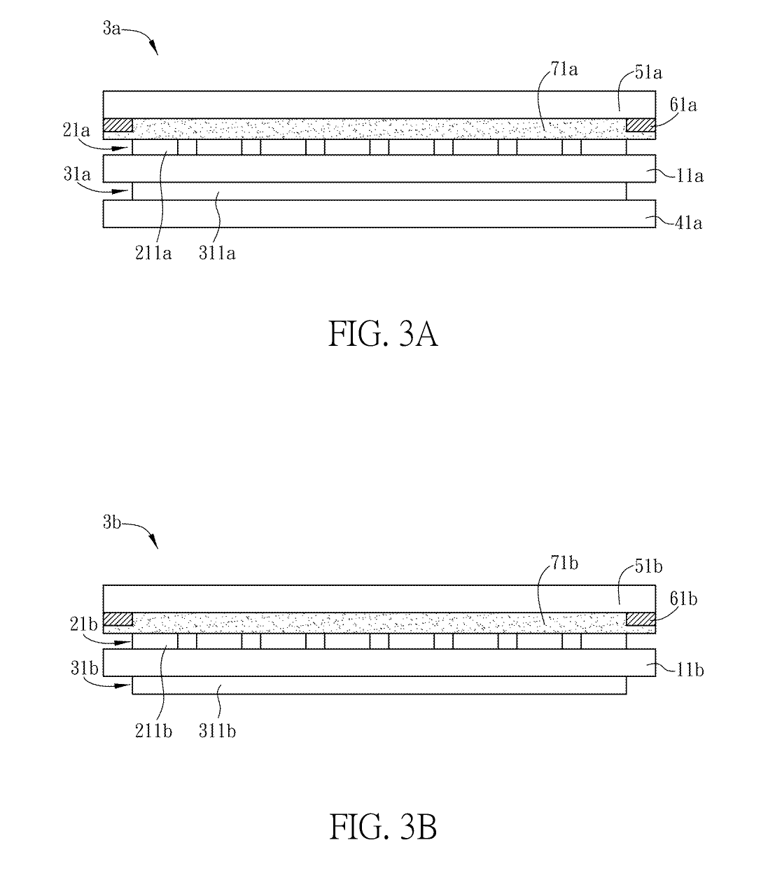

Please refer to FIG. 3A and FIG. 3B, which are schematic diagrams of a panel 3a with the sensing structure and a panel 3B with the sensing structure according to embodiments of the present invention. As shown in FIG. 3A, the panel 3a is similar to the panel 1a, and also uses the photoresist adhesion layer 11a. A difference between the panel 3a and the panel 1a is that the disposing position of the first substrate 41a of the panel 3a is different from that of the first substrate 41 of the panel 1a. In this embodiment, the first substrate 41a can be adhered to the second conductive patterns 311a of the second conductive layer 31a and the protection layer 51a is disposed to be opposite to the first conductive patterns 311a of the first conductive layer 21a. The shielding layer 61a is disposed on borders of the protection layer 51a for shielding border traces (not shown) on the borders of the panel 3a. The adhesion layer 71a is disposed between the first conductive patterns 211a of the first conductive layer 21a and the protection layer 51a for adhering the first conductive patterns 211a of the first conductive layer 21a and the protection layer 51a.

As shown in FIG. 3B, the panel 3b also comprises a photoresist adhesion layer 11b, a first conductive layer 21b comprising first conductive patterns 211b and a second conductive layer 31b comprising second conductive patterns 311b. The panel 3b further comprises a protection layer 51b disposed to be opposite to the first conductive patterns 211b of the first conductive layer 21b; a shielding layer 61b disposed on borders of the protection layer 51b′ and an adhesion layer 71b disposed between the first conductive patterns 211b of the first conductive layer 21b and the protection layer 51b.

Since the first substrates 41a, 41b, the protection layers 51a, 51b, the shielding layers 61a, 61b and the adhesion layers 71a, 71b have the same features with abovementioned first substrate 41, the protection layer 51, the shielding layer 61 and the adhesion layer 71, respectively, thus are not narrated herein for brevity.

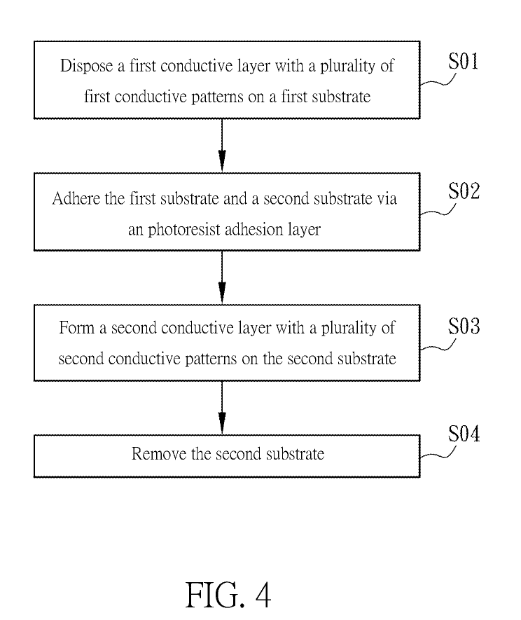

Please jointly refer to FIG. 2 and FIG. 4, which is a flow chart of a manufacturing method according to an embodiment of the present invention. The manufacturing method is utilized for manufacturing the abovementioned panel 1a and comprises steps S01-S04.

Step S01 is disposing a first conductive layer 21 on a first substrate and make the first conductive layer 21 forms a plurality of first conductive patterns 211. In this embodiment, when the first conductive patterns 211 are the metal conductive patterns, the first substrate 41 can be first served; the first substrate 41 is a transparent membranous substrate; and the materials of the first substrate 41 is the polyimide or a polyethylene terephthalate with flexibility, for example. The material of the metal conductive patterns is a photosensitive conductive material comprising photosensitive resin mixtures and a plurality of silver particles. In a realization, the diameters of the sliver particles are within 1 nm to 100 nm, or 1 nm to 50 nm preferably. The metal conductive patterns can be disposed on the first substrate 41 via the screen printed method and etching de-inking process; or via the exposure development method according to the lithography process.

Please refer to FIG. 1C, when the first conductive patterns 211 are the transparent conductive patterns (e.g. the ITO) , the first conductive patterns 211 can be formed by patterning the ITO on the internal substrate 212 since the internal substrate 212 is coated by the ITO when the third party provides the materials, and then the internal substrate 212 is adhered to the substrate 41 via the first conductive patterns 211. In such a condition, a side of the first substrate 41 equips with the structure shown in FIG. 1C.

Step S02 is adhering the first substrate 41 to a second substrate via a photoresist adhesion layer 11. In this embodiment, the materials of the photoresist adhesion layer 11 comprises the resin and the sensitizer and the photoresist adhesion layer 11 can be formed on the first conductive patterns 211 of the first conductive layer 21 or on the second substrate via a spin coating method. The material of the second substrate is the transparent membranous substrate which is also the material of the first substrate 41. A side of the second substrate equips with a photosensitive conductive material. In a realization, the first conductive patterns 211 of the first conductive layer 21 on the first substrate 41 or the internal substrate 212 of the first conductive layer 21 (as shown in FIG. 1C) is adhered to the side of the second substrate equipped with the photosensitive conductive material via utilizing the resin of the photoresist adhesion layer 11 as the adhesive. Please note that, when performing adhering or before performing adhering, a pressurized baking process may be performed, simultaneously, for softening the solid-state photoresist adhesion layer 11 via arising temperature to 100° C.-130° C., to make the photoresist adhesion layer 11 becomes adhesive, and thereby the first substrate 41 can be adhered to the second substrate effectively.

Step S03 is forming the second conductive layer 31 comprising the plurality of the conductive patterns 311. Noticeably, although the second substrate equips with the photosensitive conductive material, originally, the second conductive layer 31 is formed after step S03 is performed. In this embodiment, the lithography process is performed on the side opposite to the side of the second substrate adhered to the first substrate 41, for making the photosensitive conductive material becomes the second conductive patterns 311. Please note that, the second substrate adopts transparent materials for allowing the lithography process performed through the second substrate to be achieved.

Step S04 is removing the second substrate. In this embodiment, after the second conductive patterns 311 has formed on the second substrate and the first conductive patterns 211 and the second conductive patterns 311 have adhered to the photoresist adhesion layer 11, the second substrate is removed via a mechanical stripping method, for example, and the first substrate 41 is kept as shown in FIG. 2.

The manufacturing method further comprises forming a shielding layer 61 on borders of a protection layer 51; adhering the first substrate 41 and the protection layer 51 via an adhesion layer 71 (as shown in FIG. 2). In this embodiment, the materials of the shielding layer 61 comprises are insulation materials or inks with various colors which are insulated and the shielding layer 61 can be disposed on the borders of the protection layer 51 via a printing method an adhering method for shielding the border traces neighbored the first conductive patterns 211 and the second conductive patterns 311. The adhesion layer 71 is the optically clear adhesive or the same materials of the adhesion layer 11, for example. The adhesion layer 71 is utilized for adhering the first substrate 41 to the protection layer 51. Besides, the materials of the protection layer 51 can be the Polyimide, a Polyethylene terephthalate or the thin flexible glass and the protection layer 51 is utilized for protecting the touch sensing circuit.

Moreover, the steps S01-S04 of the abovementioned manufacturing method also can be utilized to manufacture the panel 3a and the panel 3b. Since the structure of the panel 1a is different from that of the panel 3a or that of the panel 3b, the manufacturing method needs to be modified. Please refer to FIG. 3A, in the process of manufacturing the panel 3a, a step of forming a shielding layer 61a on borders of the protection layer 51a and a step of adhering the first conductive patterns 211a to the protection layer 51a via an adhesion layer 71a are performed after the step S04. In this embodiment, the first substrate 41a is adhered to the second conductive patterns 311a. The protection layer 51a is disposed to be opposite to the first conductive patterns 211a. The shielding layer 61a is disposed on the borders of the protection layer 51a, for shielding the border traces on the border of the panel 3a. The adhesion layer 71a is disposed between the first conductive patterns 211a and the protection layer 51a, for adhering the first conductive patterns 211a to the protection layer 51a.

Please refer to FIG. 3B, in the process of manufacturing the panel 3b, a step of removing the first substrate and forming a shielding layer 61b on borders of the protection layer 51b and a step of adhering the first conductive patterns 211b to the protection layer 51b are performed after the step S04 . In this embodiment, the materials of the protection layer 51b can be the Polyimide, a Polyethylene terephthalate or the thin flexible glass. The shielding layer 61b is disposed on the borders of the protection layer 51a, for shielding the border traces . The adhesion layer 71b is the optical clear adhesive, for example, and is utilized for adhering the first conductive patterns 211a to the protection layer 51a.

Please note that, the panels 1a, 2a, 2b can be adhered to a LCD module via the optical clear adhesive or other connection components, to form a touch displayer.

To sum up, the panel with the sensing structure and manufacturing method thereof of the above embodiments are suitable for a touch sensing medium utilizing metal conductive patterns with high transmittance, high conductivity and flexibility as the conductive layer. The panel with the sensing structure and manufacturing method thereof of the above embodiments can replace semiconductor oxides of the conventional process which are high cost and low yield, and are provided with advantages of allowing products to be thinner and flexible and simplifying the process. For retaining current instrument cost and high practicality, the present invention also can incorporate with the semiconductor oxides since the emphasis of the above embodiments is utilizing the photoresist adhesion layer with high transmittance for performing adhesion, such that the power consumption of the display module is reduced and the viewing brightness is increased, effectively.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A panel with a sensing structure, comprising:
a photoresist adhesion layer with a first surface and a second surface opposite to the first surface;
a first conductive layer with a plurality of first conductive patterns disposed on the first surface along a first direction in sequence; and
a second conductive layer with a plurality of second conductive patterns disposed on the second surface along a second direction in sequence.

2. The panel of claim 1, wherein the plurality of first conductive patterns or the plurality of second conductive patterns are metal conductive patterns.

3. The panel of claim 2, wherein materials of the plurality of conductive patterns comprise a plurality of sliver particles when the plurality of conductive patterns are the metal conductive patterns.

4. The panel of claim 3, wherein a diameter of each of the plurality of silver particles is within 1 nm to 100 nm.

5. The panel of claim 1, wherein the first conductive layer comprises an internal substrate; the plurality of first conductive patterns are transparent conductive patterns; and the plurality of first conductive patterns are formed on the internal substrate and are disposed on the photoresist adhesion layer via the internal substrate.

6. The panel of claim 1, wherein the plurality of first conductive patterns extend along the second direction and the plurality of second conductive patterns extend along the first direction;
wherein the first direction is perpendicular to the second direction.

7. The panel of claim 1, further comprising:
a first substrate, disposed on the first conductive layer;
a protection layer, disposed to be opposite to the first substrate;
a shielding layer, disposed on borders of the protection layer; and
an adhesion layer, disposed between the first substrate and the protection layer.

8. The panel of claim 7, wherein the first substrate or the external substrate is a flexible transparent substrate.

9. The panel of claim 1, further comprising:
an external substrate, adhered to the second conductive layer;
a protection layer, disposed to be opposite to the first conductive layer;
a shielding layer, disposed on borders of the protection layer; and
an adhesion layer, disposed between the first conductive layer and the protection layer.

10. The panel of claim 9, wherein the first substrate or the external substrate is a flexible transparent substrate.

11. The panel of claim 1, further comprising:
a protection layer, disposed to be opposite to the first conductive layer;
a shielding layer, disposed on borders of the protection layer; and
an adhesion layer, disposed between the first conductive layer and the protection layer.

12. A manufacturing method of a panel with a sensing structure, comprising:
disposing a first conductive layer with a plurality of a plurality of first conductive patterns on a first substrate;
adhering the first substrate and a second substrate via a photoresist adhesion layer;
forming a second conductive layer with a plurality of the second conductive patterns on the second substrate; and
removing the second substrate.

13. The manufacturing method of the claim 12, wherein the first conductive layer comprises an internal substrate; the plurality of first conductive patterns are transparent conductive patterns; and the plurality of first conductive patterns are formed on the internal substrate and are adhered to the photoresist adhesion layer via the internal substrate.

14. The manufacturing method of claim 12, further comprising:
forming a shielding layer on borders of a protection layer; and
adhering the first substrate and the protection layer via an adhesion layer.

15. The manufacturing method of claim 12, further comprising:
forming a shielding layer on borders of a protection layer; and
adhering the second conductive layer and the protection layer via an adhesion layer.

16. The manufacturing method of claim 12, further comprising:
removing the first substrate;
forming a shielding layer on borders of a protection layer; and
adhering the first conductive layer and the protection layer via an adhesion layer.

17. The manufacturing method of claim 12, wherein the plurality of first conductive patterns or the plurality of second conductive patterns are metal conductive patterns.

18. The manufacturing method of claim 17, wherein materials of the plurality of conductive patterns comprise a plurality of silver particles when the plurality of conductive patterns are metal conductive patterns.

19. The manufacturing method of claim 18, wherein a diameter of each of the plurality of silver particles is within 1 nm to 100 nm.
